(19) United States
(12) Patent Application Publication
(10) Pub. No.: US 2007/0164772 A1
(43) Pub. Date: Jul. 19, 2007

(54) Micro-array inertia sensing system based single chip device

(76) Inventor: Jux Win, Hsinchu (TW)

Correspondence Address: MICHAEL W. TAYLOR, P.O. BOX 3791, ORLANDO, FL, 32802-3791, US

(21) Appl. No.: 11/518,711

(22) Filed: Sep. 11, 2006

(30) Foreign Application Priority Data
Jan. 18, 2006 (TW) 095101972

(51) Int. Cl. G01R 31/26

(52) U.S. Cl. 324/765

(57) ABSTRACT

The proposed single chip device includes a plurality of sense units arranged in a matrix form and each including a metal layer swingable in plural degrees of freedom, a metal post running vertically through a center point of the sense units and connected with the metal layer, an electrode structure disposed below and in parallel with the metal layer and including a plurality of activation electrodes each forming a capacitance with the metal layer, a plurality of sense electrodes sensing a plurality of capacitances formed between the activation electrodes and the metal layer, respectively, to obtain capacitance signals for the capacitances and a stop member to limit the metal layer to swing over a specific range and a circuit receiving the capacitance signals for the capacitances. And the provided device is deposited on an object to determine an inertia of the object.

### FIELD OF THE INVENTION

The present invention relates to an inertia sensing system based single chip device for sensing inertia of an object on which the single chip device is applied, and particularly to a micro-array inertia sensing system based single chip having metal layers supported on metal posts for sensing the same.

### BACKGROUND OF THE INVENTION

Inertia sensing technology has been widely employed in the accelerometer, earthquake detecting means, sensor of the car security bladder, golf training equipment, projector, scanner (barcode machine and laser scanner) etc. for sensing inertia thereof. For the currently used inertia sensing technologies, they are generally implemented by means of huge mechanical systems. For single chip implementations, the huge mechanical systems are directly scaled down and formed in a single chip. However, the mechanical structures integrally fabricated in the single chip are generally different from those of the traditional mechanical systems in characteristics.

Referring to FIG. 1, a conventional inertia sensing system based single chip device is schematically shown therein. As shown, the inertia sensing system based single chip includes a main body 1 and a circuit 2. The circuit 2 is used to control the main body 1 to conduct the inertia sensing task. The main body 1 includes a capacitor (not shown), which moves along a line for inertia sensing. Since the single chip device can be considered as a miniaturized form of a traditional mechanical system, a single structure form or a symmetric dual structure form is inherent in the main body 1. The main drawbacks of such a single chip device are that relatively the fabrication process, which employs the IC technologies to manufacture the main body 1, is difficult, the defective rate thereof is high and the reliability of the single chip device could be reduced by the losses suffered from the use thereof. Further, since the sensing capacitor is moved in a traverse direction, the single structure form of main body 1 can only conduct the inertia sensing task along a single degree of freedom. In this design, the volume of the single chip device is not easy to be miniaturized and the main body 1 is limited with poor flexibility in size design.

In light of the above shortcomings, the inventor sets forth a micro-array inertia sensing system based single chip device capable sensing inertia in any direction and with relatively higher reliability and sensitivity, by employing the advantages of the existing integral circuit technologies, after a series of intensive researches, experiments and tests. Further, a four-quadrant activation and sense electrodes structure is employed in the single chip device of the present invention to achieve the inertia sensing and sense controlling functions.

### SUMMARY OF THE INVENTION

It is, therefore, an object of the present invention to provide a micro-array inertia sensing system based single chip device, so as to achieve the inertia sensing and sense controlling functions.

According to one aspect of the present invention, a single chip device is disclosed, which can achieve the above purposes and includes a plurality of sense units arranged in a matrix form and a circuit. Each of the plurality of sense units includes a metal layer; a metal post running vertically through a center point of the sense unit and connected with the metal layer, wherein the metal layer is swingable in plural degrees of freedom, an electrode structure disposed below and in parallel with the metal layer, including a plurality of activation electrodes disposed symmetrically with respect to the center point and each forming a capacitance with the metal layer, a plurality of sense electrodes disposed symmetrically with respect to the center point and circumferentially with respect to the plurality of activation electrodes and sensing a plurality of capacitances between each of the plurality of activation electrodes and the metal layer, respectively, to obtain a capacitance signal for each of the plurality of capacitances and a stop member disposed circumferentially with respect to the plurality of sense electrodes so as to limit the metal layer to swing over a specific range and a circuit receiving the capacitance signal associated with each of the plurality of capacitances to determine an inertia of an object on which the single chip device is applied.

In an embodiment, the circuit further sends an autozero signal by referring to the capacitance signal for each of the plurality of capacitances to drive the metal layer to a horizontal position, when required.

In an embodiment, the circuit refers to the capacitance signal for each of the plurality of capacitances by calculating a plurality of capacitance differences among the plurality of capacitances.

In an embodiment, the autozero signal is a direct current (DC) voltage signal.

In an embodiment, at least a spare sense unit identical to each of the plurality of sense units is provided for spare use.

In an embodiment, the circuit selects the plurality of sense units and the at least a spare sense unit by using a specific addressing method.

In an embodiment, the plurality of sense units are disposed directly on the circuit.

In an embodiment, the metal layer is supported on the metal post.

In an embodiment, each of the metal layer and the stop member has a shape corresponding to that of each of the plurality of activation electrodes and sense electrodes.

In an embodiment, the shape is selected from the group consisting of a circular shape, a square shape, a rectangular shape and a triangular shape.

In an embodiment, the plurality of activation electrodes are disposed circumferentially with respect to the center point in an equidistant arrangement and the plurality of sense electrodes are disposed circumferentially with respect to the plurality of activation electrodes in an equidistant arrangement.

In an embodiment, the plurality of activation electrodes and sense electrodes are respectively disposed at four quadrants formed with respect to the center point.

In an embodiment, the metal layer has a plurality of openings.

In an embodiment, the single chip device has a mass and a coefficient of elasticity and each of the plurality of openings has a damping, wherein the mass, the coefficient and the damping are designated based on an acceleration of gravity on which the single chip device is operated.

In an embodiment, the single chip device has a mass and a coefficient of elasticity and each of the plurality of openings has a damping, wherein the mass, the coefficient and the damping are designated based on a sensitivity demanded by an application associated with the object on which the single chip is operated.

In an embodiment, the metal layer is made of a material different from that of the metal post, and the metal post has a cross section of a rectangular shape.

In an embodiment, the metal layer has a uniform thickness across a range thereof.

In an embodiment, the inertia is the acceleration and an azimuth.

In accordance with another aspect of the present invention, a sensing device is disclosed, which includes an electrically conductive balance pointer piece, electrically conductive supporting means for supporting and connecting with the electrically conductive balance pointer piece, a plurality of electrodes disposed circumferentially with respect to the electrically conductive supporting means, sensing means for sensing a plurality of capacitances between the electrically conductive balance pointer piece and the corresponding one of the plurality of electrodes, respectively so as to obtain a capacitance signal for each of the plurality of capacitances, and a control circuit receiving the capacitance signal for each of the plurality of capacitances to generate an inertia of an object on which the sensing device is applied.

In an embodiment, the control unit further sends an autozero signal by referring to the capacitance signal for each of the plurality of capacitances to drive the electrically conductive balance pointer piece to a balance position, when required.

Other objects, advantages and efficacies of the present invention will be described in detail below taken from the preferred embodiments with reference to the accompanying drawings.

### BRIEF DESCRIPTION OF THE DRAWINGS

The foregoing summary, as well as the following detailed description of the preferred embodiments, is better understood when read in conjunction with the appended drawings. It is understood, however, that the invention is not limited to the specific arrangements as disclosed or illustrated.

In the drawings:

FIG. 1 is a schematic diagram of a conventional inertia sensing system based single chip device;

FIG. 2 is a schematic view of an array of sense units in a micro-array inertia sensing system based single chip device according to an embodiment of the present invention;

FIG. 3 is a cross sectional view of the micro-array inertia sensing system based single chip device according to the embodiment of the present invention;

FIG. 4 is a top view of an electrode structure of one of the sense units of the micro-array inertia sensing system based single chip device according to the embodiment of the present invention; and

FIG. 5 is a block diagram illustrating how a static random access memory (SRAM) addresses the to-be-activated sense units in the micro-array inertia sensing system based single chip device.

### DETAILED DESCRIPTION OF THE PREFERRED EMBODIMENT

The present invention discloses a micro-array inertia sensing system based single chip device, which will be described taken with the preferred embodiments. By referring thereto, persons skilled in the art may implement the present invention in many other forms of embodiment. The embodiments disclosed in the following are merely preferred ones and should not be considered limitative in scope.

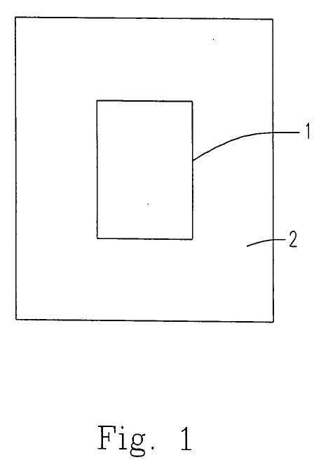

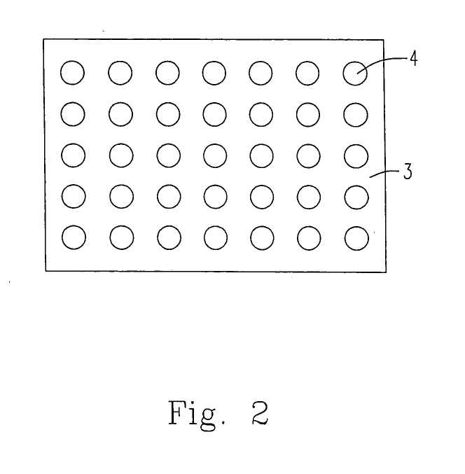

Referring to FIG. 2, a schematic view of an array of sense units in a micro-array inertia sensing system based single chip device according to an embodiment of the present invention is shown therein. In which, the sense unit array 4 is distinctive over the sense unit 1 of the conventional single chip device of FIG. 1. Further, the sense unit array 4 of the present single chip device 3 is capable of sensing the relative displacement, azimuth and acceleration of an object along a plane, on which the single chip device 3 locates, in any direction, which is also contrary to the prior art case where only the relative motion of a single direction can be sensed and the relative displacement, azimuth and acceleration of multiple directions can only be sensed by providing more inertia sensing systems with the number thereof identical to that of the motive directions as required to be sensed in the single chip device. In addition, the sense units of the sense unit array 4 may be provided with one or more spare sense units of the sense unit array 4 as a redundancy scheme, so that the spare sense units of the sense unit array 4 may be used whenever one or more of the sense units of the sense unit array 4 in the single chip device are failed. Preferably, the number of the spare sense unit of the sense unit array 4 may be one or more. In addition, the spare sense unit of the sense unit array 4 may be provided not only replacing the original sense units of the sense unit array 4 but also enhancing the functions. For example, a self-test function can be provided. In doing this, a predetermined environment may be provided to the single chip device 3 and the spare sense unit of the sense unit array 4 may be separately activated to see whether the single chip device 3 can read out the precise acceleration and azimuth values.

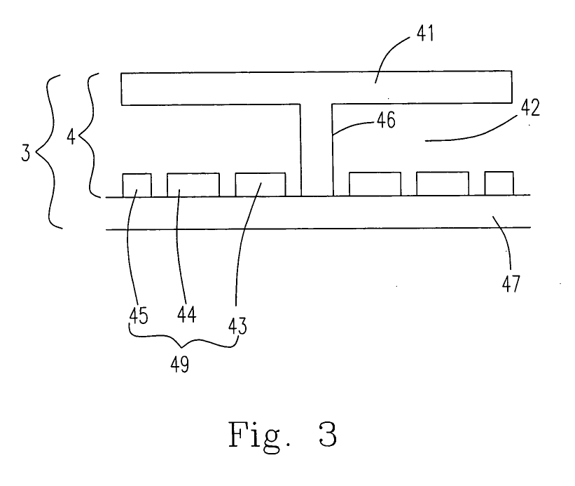

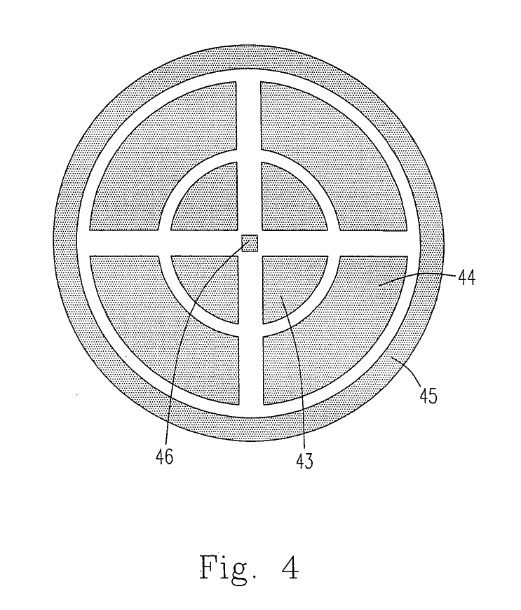

Referring FIG. 3 and FIG. 4, which are a cross sectional view of the micro-array inertia sensing system based single chip device 3 according to the embodiment of the present invention and a top view of an electrode structure of the sense units of the sense unit array 4 described above, respectively. In the structure's perspective, each of the sense units of the sense unit array 4 includes a metal layer 41, a dielectric layer 42, a metal post 46, the electrode structure 49 and a circuit 47. The metal layer 41 is disposed on and connected with the metal post 46, and has a uniform thickness thereacross and a plurality of openings (not shown) running therethrough. Specifically, the metal layer 41 and the metal post 46 are connected at a normal angle. The metal post 46 is located on a center point of the sense units of the sense unit array 4. As such, the metal post 46 can swing in two degrees of freedom when there is an acceleration or azimuth change of an object along a plane, on which the single chip device 3 is applied. Depending on the application, the materials used for the metal post 46 and the metal layer 41 may be different. In case of the metal layer 41 with a circular shape, the metal layer can swing uniformly in any direction. In case of the meal layer 41 with a rectangular shape, a portion of the swinging action thereof corresponding to a relatively longer side of the metal post 46 is limited. In case of the metal layer 41 with a square shape, the metal layer 41 is allowed to swing uniformly in the directions associated with the four sides thereof while the swinging action associated with the four corners of the metal layer 41 is not identical thereto in the limiting extent. The electrode structure 49 is disposed in parallel with and corresponding to the metal layer 41 and includes a plurality of activation electrodes 43 and a plurality of sense electrodes 44. Specifically, the plurality of activation electrodes 43 are disposed below the metal layer 41 and circumferentially and symmetrically with respect to the metal post 46 in an equidistance arrangement. The plurality of sense electrodes 44 is disposed circumferentially and symmetrically with respect to the plurality of activation electrodes 43 in a one-to-one relationship. In fact, the plurality of sense electrodes 44 and the activation electrodes 43 may be arranged other than the one-to-one relationship, as long as the sense electrodes 44 can provide the required function described below. In an embodiment, the plurality of activation electrodes 43 and the plurality of sense electrodes 44 are disposed at four quadrants formed with respect to the center point, i.e., the metal post 46. However, the sense electrodes 44 may be non-uniformly distributed. In an embodiment, each of the four quadrants has an activation electrode 43 and a sense electrode 44 disposed thereon. The electrode structure 49 may be formed as circular, square, rectangular and triangular shapes. Furthermore, the electrode layer 49 also includes a stop member 45, which is disposed circumferentially with respect to the sense electrodes 44. The stop member 45 is provided in prevention of an excessive swing amount of the metal layer 41, so that the metal layer 41 can be prevented from contacting the sense electrodes 44. In an embodiment, the stop member 45 is made of metal and connected to ground.

For forming the sense units of the sense unit array 4 by using the conventionally integrated circuit (IC) manufacturing process, the dielectric layer 42 has to be formed on the electrode structure 49 before the metal layer 41 is formed. Then, the dielectric layer 42 has to be removed so that a space between the electrode structure 49 and the metal layer 41 for swinging of the metal layer 41 can be obtained. Through the openings of the metal layer 41, an etchant liquid may be flown onto and thus etches the dielectric layer 42 away. In this manner, the dielectric layer 42 is removed and the etching process may be efficient and time saving. There is another reason for the provision of the openings. They are each used to provide a channel for air existing between the metal layer 41 and the dielectric layer 42 to be released therefrom in the manufacturing process, so that the metal layer 41 can swing in response to the object motion in a more sensitive manner. The larger these openings are, the more the released air is. Correspondingly, each of the openings has a reduced damping and thus the sense unit 4 also has a reduced damping.

Between the metal layer 41 and each of the plurality of activation electrode 43 and sense electrodes 44, there is a capacitance formed. When the metal layer 41 swings, each of these capacitances has a change. By determining these capacitance changes, the acceleration and azimuth changes of the object along a plane, on which the single chip device 3 is applied, can be obtained. To determine the capacitance change for each of the capacitances corresponding to the activation electrodes 43, the sense electrodes 44 are used to sense the capacitances corresponding to the activation electrodes 43 so as to generate a plurality of capacitance signals, and a circuit 47 is provided to receive the plurality of capacitance signals so as to obtain the capacitance change for each of the capacitance corresponding to the activation electrodes 43. With these capacitance changes obtained, the acceleration and the azimuth changes can be determined. Similarly, the above-described concept is identically applied to all the sense units of the single chip device. As such, the capacitance signals can be effectively amplified and the acceleration and azimuth can be precisely obtained without being limited by the computing sensitivity provided by the circuit 47.

To recover the metal layer 41 from a declination state so that a next sensing action can be performed thereby, the metal layer 41 may be electrically driven back to a balance state. At this time, the circuit 47 may generate an autozero signal to the activation electrodes 43 to cause the metal layer 41 to come back to the balance state by referring to the determined capacitance changes. In an embodiment, the circuit 47 generates the autozero signal by calculating capacitance changes among the plurality of capacitances. In an embodiment, the autozero signal is a direct voltage (DC) bias. In fact, the capacitance differences among the plurality of capacitances may also be used in replace of the capacitance changes for determining the acceleration and azimuth changes of the object along a plane, on which the single chip device is applied.

The sense units may be directly disposed on the circuit 47 with some proper connections therebetween. In this manner, the single chip device 3 may take up a reduced area. In addition, the circuit 47 is generally supported on a substrate (not shown). In addition, the circuit 47 may be added with an analog to digital function and a wireless transmission function. With the analog to digital function, the analog capacitance signals received can be used to generate a digital form of the autozero signal. With the wireless transmission function, the determined acceleration and azimuth changes may be read out by sending a wireless signal associated therewith.

To adapt the single chip device 3 to be used in different gravity environments and different sensitivity demanding applications, some parameters of the elements in the single chip device 3 should be properly chosen. These parameters comprise mass, coefficient of elasticity and damping of the single chip device 3. The mass of the single chip device 3 depends on area and thickness of the metal layer 41, which are in a proportional relationship with each other. The coefficient of elasticity of the single chip device 3 is in a proportional relationship with the height of the metal post 46 while in an inverse proportional relationship with an outer diameter of the metal post 46. In addition, the coefficient of elasticity of the single chip device 3 also depends on the material of the metal post 46. By choosing the above parameters, a plurality of specifications of the single chip device 3 may be provided.

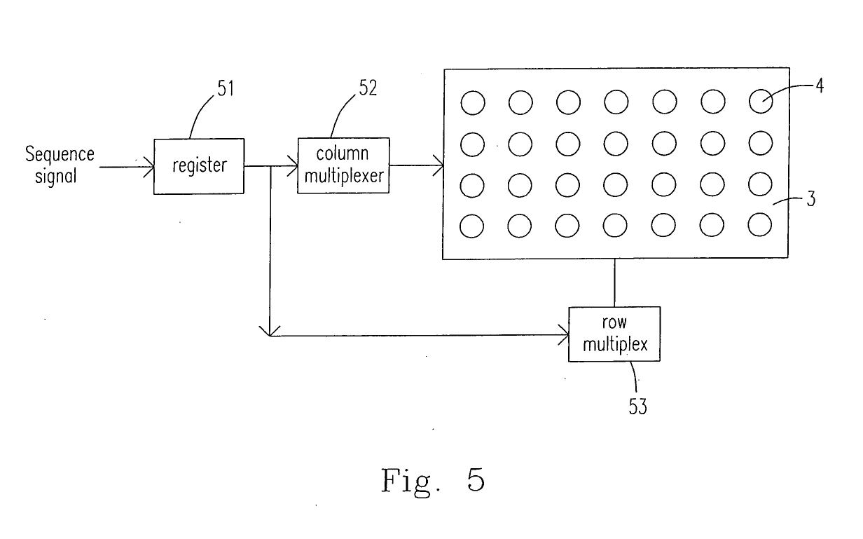

Referring to FIG. 5, which is a block diagram illustrating how a static random access memory (SRAM) addresses the to-be-activated sense units in the single chip device. As mentioned above, the spare sense unit may be used in place of a failed sense unit. To achieve this purpose, a sense unit selection system should be provided. The system includes the single chip device 3, a column multiplexer 52, a row multiplexer 53 and a register 51. In selecting the active sense units, a sequence signal is inputted to the register 51, the sequence signal including a set or a plurality sets of column and row activation/disactivation information. Then, the sequence signal in the register 51 is transmitted into the column multiplexer 52 and the row multiplexer 53. Then, the sense units and the spare sense units are activated or disactivated according to the column and row activation/disactivation information.

In conclusion, since the sense units of the single chip device, particularly the metal layer, is fabricated by using the standard IC manufacturing process, the geometrical parameters (mass, coefficient of elasticity and damping of the metal layer) of the single chip device are relatively easier to be controlled. In this case, relatively the required post semiconductor manufacturing process is easy to be performed and has a reduced variation involved therein. Further, since the sense units are presented in an array form instead of one single sense unit, the capacitance signal obtained from between the electrode structure and the metal layer can be effectively amplified. In addition, the provision of the spare sense unit can be an effective solution to the issue of sense unit failure. Besides, the generation and issuance of the autozero signal may provide a self-test function to assure that a current inertia sensing function can be performed correctly, i.e. in a condition where the metal layer is maintained balanced. Furthermore, to broadly encompass what the inventor envisages, the metal layer can be broadened to an electrically conductive balance pointer piece and the metal post can be replaced with electrically conductive support means, as long as they are suitable in achieving the same function.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. A single chip device, comprising:
a plurality of sense units arranged in a matrix form and each comprising:
a metal layer;
a metal post running vertically through a center point of the sense unit and connected with the metal layer, wherein the metal layer is swingable in plural degrees of freedom;
an electrode structure disposed below and in parallel with the metal layer, comprising:
a plurality of activation electrodes disposed circumferentially and symmetrically with respect to the center point and each forming a capacitance with the metal layer;
a plurality of sense electrodes disposed circumferentially and symmetrically with respect to the center point and the plurality of activation electrodes and sensing a plurality of capacitances formed between each of the plurality of activation electrodes and the metal layer, respectively, to obtain a capacitance signal for each of the plurality of capacitances; and
a stop member disposed circumferentially with respect to the plurality of sense electrodes so as to limit the metal layer to swing over a specific range; and
a circuit receiving the capacitance signal for each of the plurality of capacitances to determine an inertia of an object on which the single chip device is applied for each of the plurality of sense units.

2. The single chip device as claimed in claim 1, wherein the circuit further sends an autozero signal by referring to the capacitance signal for each of the plurality of capacitances to drive the metal layer to a horizontal position, when required.

3. The single chip device as claimed in claim 2, wherein the circuit refers to the capacitance signal for each of the plurality of capacitances by calculating a plurality of capacitance differences among the plurality of capacitances.

4. The single chip device as claimed in claim 3, wherein the autozero signal is a direct current (DC) voltage bias.

5. The single chip device as claimed in claim 1, further comprising at least a spare sense unit identical to each of the plurality of sense units.

6. The single chip device as claimed in claim 5, wherein the circuit selects the plurality of sense units and the at least a spare sense unit by using a specific addressing method.

7. The single chip device as claimed in claim 1, wherein the plurality of sense units are disposed directly on the circuit.

8. The single chip device as claimed in claim 1, wherein the metal layer is supported on the metal post.

9. The single chip device as claimed in claim 1, wherein each of the metal layer and the stop member has a shape corresponding to that of each of the plurality of activation electrodes and sense electrodes.

10. The single chip device as claimed in claim 9, wherein the shape is selected from the group consisting of a circular shape, a square shape, a rectangular shape and a triangular shape.

11. The single chip device as claimed in claim 1, wherein the plurality of activation electrodes are disposed in an equidistant arrangement and the plurality of sense electrodes are disposed in an equidistant arrangement.

12. The single chip device as claimed in claim 11, wherein the plurality of activation electrodes and sense electrodes are respectively uniformly disposed at four quadrants formed with respect to the center point.

13. The single chip device as claimed in claim 1, wherein the metal layer has a plurality of openings.

14. The single chip device as claimed in claim 1, wherein the single chip device has a mass and a coefficient of elasticity and each of the plurality of openings has a damping, wherein the mass, the coefficient and the damping are designated based on an acceleration of gravity on which the single chip device is operated.

15. The single chip device as claimed in claim 1, wherein the single chip device has a mass and a coefficient of elasticity and each of the plurality of openings has a damping, wherein the mass, the coefficient and the dampings are designated based on a sensitivity demanded by an application associated with the object on which the single chip is operated.

16. The single chip device as claimed in claim 1, wherein the metal layer is made of a material different from that of the metal post, and the metal post has a cross section of a rectangular shape.

17. The single chip device as claimed in claim 1, wherein the metal layer has a uniform thickness across a range thereof.

18. The single chip device as claimed in claim 1, wherein the inertia is sensed by sensing an acceleration and an azimuth of the object on which the single chip device is applied.

19. A sensing device, comprising:
an electrically conductive balance pointer piece;
electrically conductive support means for supporting and connecting with the electrically conductive balance pointer piece;
a plurality of electrodes disposed circumferentially and symmetrically with respect to the electrically conductive supporting means;
sensing means for sensing a plurality of capacitances between the electrically conductive balance pointer piece and the plurality of electrodes, respectively, so as to obtain a capacitance signal for each of the plurality of capacitances; and
a control circuit receiving the capacitance signal for each of the plurality of capacitances to generate an inertia value of an object on which the sensing device is applied according to the capacitance signal for each of the plurality of capacitances.

20. The sensing device as claimed in claim 19, wherein the control unit further sends an autozero signal by referring to the capacitance signal for each of the plurality of capacitances to drive the electrically conductive balance pointer piece to a balance position, when required.
